(19) United States
(12) Patent Application Publication
(10) Pub. No.: US 2025/0248275 A1
(43) Pub. Date: Jul. 31, 2025

(54) DISPLAY APPARATUS

(71) Applicant: LG Display Co., Ltd., Seoul (KR)

(72) Inventors: Heeyeon HWANG, Paju-si (KR); SangHoon OH, Paju-si (KR)

(21) Appl. No.: 18/974,066

(22) Filed: Dec. 9, 2024

(30) Foreign Application Priority Data
Jan. 30, 2024 (KR) 10-2024-0013633

(51) Int. Cl. H10K 59/80; H10K 77/10; H10K 102/00

(52) U.S. Cl. CPC H10K 59/873; H10K 77/111; H10K 2102/311; H10K 2102/351

(57) ABSTRACT

Embodiments of the present disclosure relate to a display apparatus. The display apparatus includes a cover glass located on a display panel, and covering an area overlapping a non-folding area of a first side surface of the display panel, wherein the thickness of a part of the cover glass which covers the first side surface of the display panel and is disposed in an area overlapping the non-folding area is larger than the thickness of a part of the cover glass which is disposed in an area overlapping a folding area. It is possible to provide a display apparatus with improved impact resistance while realizing a folding function.

### CROSS-REFERENCE TO RELATED APPLICATION

This application claims priority from Korean Patent Application No. 10-2024-0013633 filed on Jan. 30, 2024, which is hereby incorporated by reference for all purposes as if fully set forth herein.

### BACKGROUND

### Technical Field

Embodiments of the present disclosure relate to a display apparatus.

### Description of Related Art

As the information age is entered, the display field that displays images has developed rapidly, and in response to this, various display apparatuses with excellent performance such as thinness, light weight and low power consumption are being developed.

Recently, the shapes and sizes of display apparatuses have gradually become diverse, and in particular, interest in flexible display apparatuses which can maintain display performance even when they are folded or rolled continues to increase.

In order to implement a flexible display apparatus, efforts are being made to thin not only a display panel but also various components included in the display apparatus.

Components included in the display apparatus may include layers (hereinafter referred to as protective layers) for protecting the display panel from the outside. However, if a protective layer is made thin to realize a flexible function, the protective layer may become vulnerable to external impact, and there is a problem that the function of protecting the display panel from the outside is not properly performed.

Therefore, it is necessary to protect the display panel from the outside by improving the impact resistance of the protective layer even while realizing a flexible function.

### BRIEF SUMMARY

Embodiments of the present disclosure may provide a display apparatus with improved impact resistance while providing a flexible function.

According to embodiments of the present disclosure, a display apparatus may include: a display panel including a first side surface and a second side surface which meets the first side surface, the first side surface including a folding area and a non-folding area around the folding area; and a cover glass located on the display panel, and covering an area which overlaps the non-folding area of the first side surface of the display panel and at least a part of the second side surface of the display panel, wherein the thickness of a part of the cover glass which covers the first side surface of the display panel and is disposed in an area overlapping the non-folding area is larger than the thickness of a part of the cover glass which is disposed in an area overlapping the folding area.

According to embodiments of the present disclosure, a display apparatus may include: a display panel including a first side surface and a second side surface perpendicular to the first side surface; and a cover glass located on the display panel, and covering at least a part of the first side surface and at least a part of the second side surface, wherein the thickness of a part of the cover glass which covers the first side surface is different from the thickness of a part of the cover glass which overlaps the first side surface and does not cover the first side surface.

According to embodiments of the present disclosure, a display apparatus may include: a display panel; and a cover glass located on the display panel, and including a first opening which overlaps one side surface of the display panel and a second opening which overlaps the other side surface of the display panel, wherein the display panel is located inside the cover glass in an area overlapping the first opening, and protrudes to an outside of the cover glass in an area overlapping the second opening.

According to the embodiments of the present disclosure, it is possible to provide a display apparatus with improved impact resistance while providing a flexible function.

According to the embodiments of the present disclosure, since the impact resistance of the display apparatus is improved and thus the need for a separate external structure for protecting the display apparatus is eliminated, it is possible to provide the display apparatus enabling process optimization.

### DESCRIPTION OF THE SEVERAL VIEWS OF THE DRAWINGS

FIG. 1 is a view illustrating an example of the three-dimensional structure of a display apparatus according to embodiments of the present disclosure.

FIG. 2 is a view illustrating an example of the cross-sectional structure, when viewed in a first direction, of the display apparatus including the structure illustrated in FIG. 1.

FIG. 3 is a view illustrating another example of the three-dimensional structure of the display apparatus according to the embodiments of the present disclosure.

FIG. 4 is a view illustrating an example of the cross-sectional structure, when viewed in a first direction, of the display apparatus including the structure illustrated in FIG. 3.

FIG. 5 is a view illustrating the structure, when viewed in a vertical direction, of the display apparatus illustrated in FIG. 3.

FIG. 6 is a view illustrating an example of the cross-sectional structure of a part I-I′ of FIG. 3.

FIG. 7 is a view illustrating an example of the cross-sectional structure of a part II-II′ of FIG. 3.

FIG. 8 is a view illustrating an example of the cross-sectional structure of a part III-III′ of FIG. 3.

FIG. 9 is a view illustrating still another example of the three-dimensional structure of the display apparatus according to the embodiments of the present disclosure.

FIG. 10 is a view illustrating an example of the cross-sectional structure of a part IV-IV′ of FIG. 9.

FIG. 11 is a view illustrating an example of the three-dimensional structure of a part of the configuration of the display apparatus illustrated in FIG. 3.

FIG. 12 is of a view and a graph for explaining impact resistance characteristics of the display apparatus according to the embodiments of the present disclosure.

FIG. 13 is of a view and a graph for explaining curvature characteristics and etch uniformity characteristics of the display apparatus according to the embodiments of the present disclosure.

FIG. 14 is of views for explaining a method of manufacturing the structure illustrated in FIG. 11.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including,” “having,” “containing,” “constituting,” “make up of” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A)” or “(B)” may be used herein to describe elements of the present disclosure. Each of these terms is not used to define essence, order, sequence, number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

When time relative terms, such as “after,” “subsequent to,” “next,” “before” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Hereinafter, various embodiments of the present disclosure will be described in detail with reference to accompanying drawings.

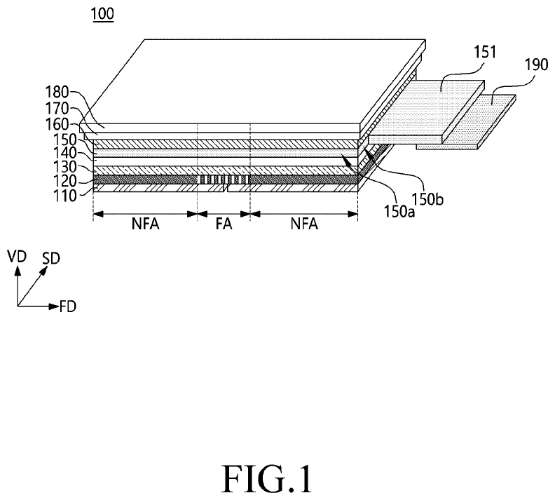

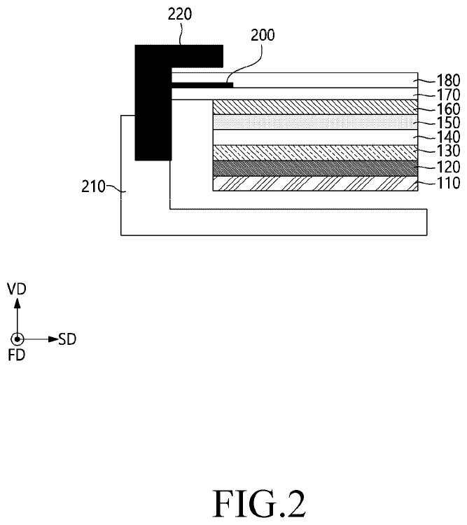

FIG. 1 is a view illustrating an example of the three-dimensional structure of a display apparatus according to embodiments of the present disclosure. FIG. 2 is a view illustrating an example of the cross-sectional structure, when viewed in a first direction, of the display apparatus including the structure illustrated in FIG. 1. FIG. 2 is a view illustrating a part of a second surface of the display apparatus.

Referring to FIGS. 1 and 2, the display apparatus 100 may include a support frame 110, a first support layer 120, a second support layer 130, a back plate 140, a display panel 150, a connection part 151 of the display panel 150, a polarizer 160, a cover glass 170, a shatterproof layer 180, a circuit part 190, a black matrix 200, a lower case 210, and an upper case 220.

The side surfaces of the display apparatus 100 may include two first surfaces which face each other and two second surfaces which are connected to the first surfaces and face each other.

The first surface and the second surface may be perpendicular to each other, but are not limited thereto.

The first surface is a surface which extends in a first direction FD, and the second surface is a surface which extends in a second direction SD.

The first surface may include a folding area FA and a non-folding area NFA which is located around the folding area FA.

The folding area FA may mean an area where the display apparatus 100 is bent, and the non-folding area NFA may mean an area where the display apparatus 100 is not bent and remains flat.

As illustrated in FIG. 1, the non-folding area NFA may be located around the folding area FA. However, the embodiments of the present disclosure are not limited thereto, and as the case may be, the folding area FA may be located around the non-folding area NFA.

The width of the folding area FA in the first direction FD may be smaller than the width of the non-folding area NFA in the first direction FD.

As will be described later, the connection part 151 of the display panel 150 may be disposed on a partial area of the second surface. The width in the second direction SD of a part of the second surface where the connection part 151 is disposed may be smaller than the width in the second direction SD of the second surface.

Hereinafter, the stack structure of the display apparatus 100 including the first surface and the second surface will be described.

The support frame 110 may be disposed at a lower part of the display apparatus 100.

The support frame 110 may serve to support the display apparatus 100 and reinforce the rigidity of the display apparatus 100.

The support frame 110 may be made of metal to reinforce the rigidity of the display apparatus 100. However, the embodiments of the present disclosure are not limited thereto.

As illustrated in FIG. 1, the support frame 110 may have at least one groove in the folding area FA. The support frame 110 may be divided into two by the groove disposed in the folding area FA.

As the support frame 110 has the groove in the folding area FA, the display apparatus 100 may be easily bent in the folding area FA.

The circuit part 190 may be attached to the lower surface of the support frame 110. In order to attach the circuit part 190 to the lower surface of the support frame 110, the connection part 151 may be bent in a direction parallel to a third direction VD.

In addition to the circuit part 190, various components may be disposed under the support frame 110. For example, a component such as a battery or the like for supplying power to the display panel 150 and the circuit part 190 may be disposed.

A plurality of support layers may be disposed on the support frame 110. The plurality of support layers may include the first support layer 120 and the second support layer 130 which is disposed on the first support layer 120.

The first support layer 120 and the second support layer 130 may serve to support the display panel 150.

The first support layer 120 may be made of metal. For example, the first support layer 120 may include stainless steel. However, the embodiments of the present disclosure are not limited thereto, and the first support layer 120 may be made of fiber reinforced plastic (FRP). For example, the first support layer 120 may be carbon fiber reinforced plastic (CFRP).

The first support layer 120 may include a plurality of grooves in the folding area FA on the first surface of the display apparatus 100. The display apparatus 100 may be easily bent in the folding area FA due to the presence of the plurality of grooves disposed in the folding area FA.

The second support layer 130 may be disposed on the first support layer 120.

The second support layer 130 may be made of metal. For example, the second support layer 130 may be stainless steel. However, the embodiments of the present disclosure are not limited thereto, and the second support layer 130 may be made of plastic including polymer. For example, the second support layer 130 may be polyimide (PI).

The second support layer 130 may also be disposed in the form of a thin film.

The back plate 140 may be disposed on the second support layer 130.

The back plate 140 may serve to reinforce the rigidity of the display panel 150.

The back plate 140 may be formed as a plastic thin film, but is not limited thereto.

The display panel 150 may be disposed on the back plate 140.

The display panel 150 may be an organic light emitting display panel, but is not necessarily limited thereto. However, the following description will be made by taking as an example a case where the display panel 150 is an organic light emitting display panel.

The display panel 150 may include a substrate, a transistor layer, a light emitting element layer, an encapsulation layer, a touch sensor layer, etc.

The substrate included in the display panel 150 may be a plastic substrate to realize a folding function.

The transistor layer may mean a layer in which transistors for driving light emitting elements and transistors for transmitting various signals and voltages to the display panel 150 are disposed.

The light emitting element layer may mean a layer in which a light emitting layer emitting red, green or blue light, a first electrode under the light emitting layer and a second electrode on the light emitting layer are disposed. The first electrode may be an anode electrode, and the second electrode may be a cathode electrode. The light emitting layer may be made of organic material.

The first electrode, the light emitting layer and the second electrode may be sequentially stacked, and a light emitting area may be formed in an area where the first electrode, the light emitting layer and the second electrode are sequentially stacked.

The first electrode of the light emitting element layer may be electrically connected to a drain electrode of the transistor layer.

The encapsulation layer may be a layer which protects the light emitting element layer from penetration of moisture or oxygen from the outside. The encapsulation layer may be a thin film encapsulation layer, but is not limited thereto.

When the encapsulation layer is a thin film encapsulation layer, the encapsulation layer may have a structure in which inorganic encapsulation layers and organic encapsulation layers are alternately stacked.

The touch sensor layer may be disposed on the encapsulation layer. The touch sensor layer may mean a layer which realizes a touch function. The touch sensor layer may include a touch electrode, a connection electrode, a touch buffer layer, etc.

The display panel 150 may include two first side surfaces 150a which correspond to the two first surfaces of the display apparatus 100 and face each other and two second side surfaces 150b which correspond to the two second surfaces of the display apparatus 100 and face each other.

The first side surface 150a and the second side surface 150b may meet each other. The first side surface 150a and the second side surface 150b may be perpendicular to each other, but are not necessarily limited thereto.

The first side surface 150a may be divided into the folding area FA and the non-folding area NFA around the folding area FA.

The connection part 151 may be disposed on the display panel 150 on the second side surface 150b.

The connection part 151 may serve to connect the display panel 150 and the circuit part 190.

The connection part 151 may be the substrate included in the display panel 150. The connection part 151 may have a shape in which a part of the substrate included in the display panel 150 extends further in the first direction FD on the second side surface 150b.

The circuit part 190 may be disposed in a partial area under the connection part 151. The circuit part 190 may include circuits which transmit various signals and voltages to the display panel 150. For example, the circuit part 190 may include a data driving circuit for supplying a data voltage to the subpixels included in the display panel 150 and a gate driving circuit for supplying a gate voltage to the subpixels included in the display panel 150. However, the circuit part 190 is not limited thereto.

FIG. 1 illustrates that the circuit part 190 is connected, in a chip-on-panel (COP) method, to the bonding pads of the connection part 151 extending from the display panel 150, but the embodiments of the present disclosure are not necessarily limited thereto. The circuit part 190 may be connected to the display panel 150 in a tape automated bonding (TAB) method, or may be connected to the display panel 150 by being implemented in a chip-on-glass (COG) method or a chip-on-film (COF) method.

The polarizer 160 may be disposed on the display panel 150. The polarizer 160 may serve to improve reflective visibility by blocking light incident from outside the display apparatus 100 from being reflected inside the display apparatus 100.

The polarizer 160 may be formed as a film with a polarizing function.

The cover glass 170 may be disposed on the polarizer 160.

The cover glass 170 may serve to protect the display panel 150.

The cover glass 170 may be made of glass (or tempered glass) or plastic, and may be made of a transparent material.

The widths in the first direction FD and the second direction SD of the cover glass 170 may be larger than the widths, respectively, in the first direction FD and the second direction SD of the polarizer 160, the display panel 150, the back plate 140, the plurality of support layers and the support frame 110.

The cover glass 170 may have a thickness of approximately 30 to 90 um in the third direction VD to realize a folding function. The thickness of the cover glass 170 may be constant on an entire plane defined by the first direction FD and the second direction SD.

Referring to FIG. 2, since the width in the second direction SD of the cover glass 170 is larger than the width in the second direction SD of the display panel 150, the cover glass 170 may protrude more than the display panel 150 in the second direction SD.

The shatterproof layer 180 may be disposed on the cover glass 170.

The black matrix 200 may be disposed between the cover glass 170 and the shatterproof layer 180.

The black matrix 200 may absorb some of the light emitted from the display panel 150. The black matrix 200 may serve to prevent light from being seen in an area other than an area where the display panel 150 is disposed.

In order to block light in the area other than the area where the display panel 150 is disposed, the black matrix 200 may be disposed outside the area where the display panel 150 is disposed. For example, as illustrated in FIG. 2, the black matrix 200 may be disposed on an area where the cover glass 170 protrudes beyond the display panel 150 in the second direction SD. However, the embodiments of the present disclosure are not limited thereto, and the black matrix 200 may be disposed to partially overlap the display panel 150.

The shatterproof layer 180 may serve to prevent debris from shattering when the cover glass 170 is broken by external impact.

The shatterproof layer 180 may have the same width as the cover glass 170.

Although not illustrated in detail in FIGS. 1 and 2, adhesive layers may be disposed between the support frame 110 and the first support layer 120, between the first support layer 120 and the second support layer 130, between the second support layer 130 and the back plate 140, between the back plate 140 and the display panel 150, between the display panel 150 and the polarizer 160 and between the polarizer 160 and the cover glass 170. The adhesive layers may serve to attach the respective layers, and may be, but not limited to, optically clear adhesive (OCA) or pressure sensitive adhesive (PSA).

The upper case 220 and the lower case 210 may be disposed on the side surfaces of the cover glass 170 and the shatterproof layer 180.

The upper case 220 and the lower case 210 may serve to protect the display panel 150 and the various layers included in the display apparatus 100 from the outside.

As illustrated in FIG. 2, the upper case 220 may cover the side surface and a part of the upper surface of the shatterproof layer 180.

In order to protect, from external impact, a part where the cover glass 170 and the shatterproof layer 180 do not overlap the area where the display panel 150 is disposed, for example, a part where, as illustrated in FIG. 2, the cover glass 170 and the shatterproof layer 180 protrude beyond the display panel 150 in the second direction SD, the upper case 220 may have a structure which is bent in the second direction SD.

Other components for driving the display panel 150 may be further disposed between the upper case 220 and the side surface of the display panel 150 or between the lower case 210 and the side surface of the display panel 150.

Likewise, other components for driving the display panel 150 may be further disposed between the lower case 210 and the support frame 110.

In the display apparatus 100 described above with reference to FIGS. 1 and 2, the cover glass 170 may include a part which protrudes beyond the area where the display panel 150 is disposed.

In order to realize the folding function of the display apparatus 100, the cover glass 170 may be formed to have a thickness of 30 um to 90 um.

As the cover glass 170 is formed to be thin from 30 um to 90 um, the part where the cover glass 170 protrudes beyond the area where the display panel 150 is disposed may be vulnerable to external impact.

Hereinbelow, measures for solving such a problem will be explained with reference to drawings.

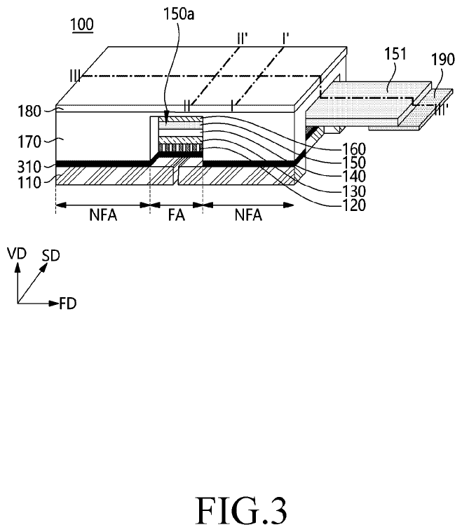

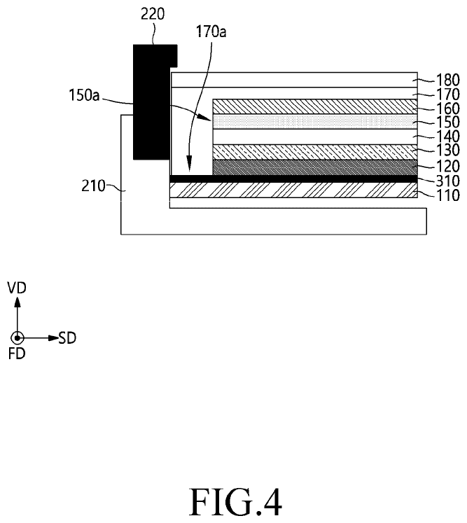

FIG. 3 is a view illustrating another example of the three-dimensional structure of the display apparatus according to the embodiments of the present disclosure. FIG. 4 is a view illustrating an example of the cross-sectional structure, when viewed in a first direction, of the display apparatus including the structure illustrated in FIG. 3. FIG. 4 is a view illustrating the cross-sectional structure of the display apparatus including a part of a second surface of the display apparatus.

Since the display apparatus 100 illustrated in FIGS. 3 and 4 is the same as the display apparatus 100 illustrated FIGS. 1 and 2 except that the structures of a support frame 110, a black adhesive layer 310, a cover glass 170 and an upper case 220 are changed, overlapping description will be omitted.

Referring to FIGS. 3 and 4, the support frame 110 may be disposed not only in an area where a display panel 150 is disposed but also in an area outside the area where the display panel 150 is disposed.

The widths in a first direction FD and a second direction SD of the support frame 110 may be larger than the widths, respectively, in the first direction FD and the second direction SD of the display panel 150.

For example, as illustrated in FIG. 4, the support frame 110 may include a part which protrudes beyond the display panel 150 in the second direction SD.

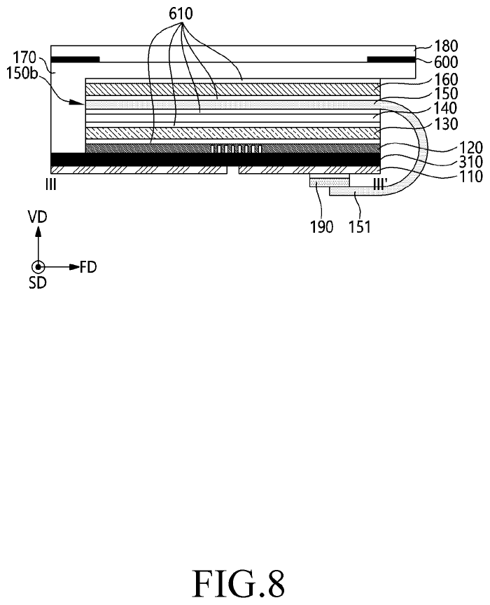

The support frame 110 may have a part which protrudes beyond the display panel 150 even in the first direction FD. This will be described later with reference to FIG. 8.

The black adhesive layer 310 may be disposed on the support frame 110. The black adhesive layer 310 may be disposed between the support frame 110 and a first support layer 120 to attach the support frame 110 and the first support layer 120.

The widths in the first direction FD and the second direction SD of the black adhesive layer 310 may be the same as the widths, respectively, in the first direction FD and the second direction SD of the support frame 110. That is to say, the outer surfaces of the black adhesive layer 310 may be on the same planes as the outer surfaces of the support frame 110.

Since the black adhesive layer 310 has the same widths as the support frame 110, the black adhesive layer 310 may include a part which protrudes beyond the display panel 150, for example, in the second direction SD. In addition, the black adhesive layer 310 may include a part which protrudes beyond the display panel 150 even in the first direction FD. In other words, the black adhesive layer 310 may be disposed in an area outside the area where the display panel 150 is disposed.

Since the black adhesive layer 310 is disposed in the area outside the area where the display panel 150 is disposed, the black adhesive layer 310 may absorb some of light emitted from the display panel 150, and may prevent light from being recognized in an area other than the area where the display panel 150 is disposed.

Therefore, even in a case where the display apparatus 100 does not include a black matrix between the cover glass 170 and a shatterproof layer 180, it is possible to prevent light from being recognized in the area other than the area where the display panel 150 is disposed.

The cover glass 170 may be disposed on a polarizer 160 and the black adhesive layer 310.

The cover glass 170 may cover both first side surfaces 150a and second side surfaces 150b of the display panel 150. Hereinafter, a case where the cover glass 170 covers the first side surface 150a of the display panel 150 will be described. A structure in which the cover glass 170 covers the second side surface 150b of the display panel 150 will be described later with reference to FIG. 8.

Referring to FIGS. 3 and 4, the cover glass 170 may extend in a direction parallel to a third direction VD in an area other than the area where the display panel 150 is disposed.

The cover glass 170 may extend in the direction parallel to the third direction VD to cover the first side surface 150a of the display panel 150.

In the area where the cover glass 170 extends in the direction parallel to the third direction VD, the first side surface 150a of the display panel 150 may contact the inner side surface of the cover glass 170.

The cover glass 170 may extend in the direction parallel to the third direction VD to contact the black adhesive layer 310. Namely, a lowermost surface 170a of the cover glass 170 may contact the upper surface of the black adhesive layer 310. The lowermost surface 170a of the cover glass 170 may be located on the same plane as the lower surface of the first support layer 120.

The distance from the lowermost surface 170a of the cover glass 170 to the upper surface of the cover glass 170 may be larger than the distance from the upper surface of the polarizer 160 to the upper surface of the cover glass 170.

The thickness of the cover glass 170 which extends in the direction parallel to the third direction VD in the area outside the area where the display panel 150 is disposed may be larger than the thickness of the cover glass 170 in the area where the display panel is disposed.

The widths in the first direction FD and the second direction SD of the cover glass 170 may be the same as the widths, respectively, in the first direction FD and the second direction SD of the black adhesive layer 310 and the support frame 110.

The outer surfaces of the cover glass 170 may be located on the same planes as the outer surfaces of the black adhesive layer 310 and the support frame 110.

The shatterproof layer 180 may be disposed on the cover glass 170.

A black matrix may not be disposed between the shatterproof layer 180 and the cover glass 170. However, the embodiments of the present disclosure are not limited thereto, and a black matrix may be disposed between the shatterproof layer 180 and the cover glass 170 as illustrated in FIG. 2. In the case where a black matrix is disposed, it is possible to more effectively prevent light from being recognized in an area outside the display panel 150.

The upper case 220 may be disposed on the side surfaces of the cover glass 170 and the shatterproof layer 180.

The upper case 220 may cover the side surfaces of the cover glass 170 and the shatterproof layer 180.

The upper case 220 illustrated in FIG. 4 may be disposed in the third direction VD. That is to say, the upper case 220 may not be bent to the second direction SD.

Because the cover glass 170 includes a part which extends in the direction parallel to the third direction VD in the area outside the area where the display panel 150 is disposed and the thickness of the cover glass 170 extending in the direction parallel to the third direction VD is larger than the thickness of the cover glass 170 illustrated in FIG. 2, the impact resistance of the cover glass 170 may be improved compared to the cover glass 170 illustrated in FIG. 2.

Also, since the cover glass 170 may cover the side surface of the display panel 150 by extending in the direction parallel to the third direction VD, it is possible to protect the display panel 150 from external impact.

Moreover, since impact resistance is improved as the cover glass 170 includes the part which extends in the direction parallel to the third direction VD, it is possible to protect the cover glass 170 from external impact even when the upper case 220 is not bent to the second direction SD as illustrated in FIG. 2.

Hereinafter, the three-dimensional structure of the cover glass 170 which has the part extending in the direction parallel to the third direction VD will be described in detail.

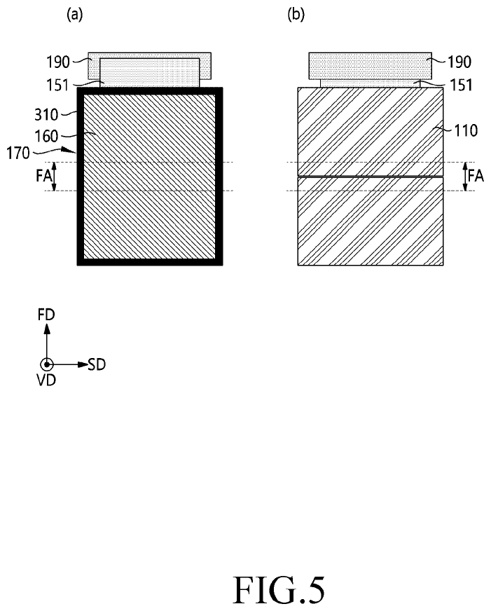

FIG. 5 is a view illustrating the structure, when viewed in a vertical direction, of the display apparatus illustrated in FIG. 3.

(a) of FIG. 5 is a view illustrating a structure when viewing the upper surface of the display apparatus 100 in the third direction VD, and (b) of FIG. 5 is a view illustrating a structure when viewing the lower surface of the display apparatus 100 in the third direction VD.

Referring to (a) of FIG. 5, as described above, the widths in the first direction FD and the second direction SD of the black adhesive layer 310 may be larger than the widths, respectively, in the first direction FD and the second direction SD of the display panel 150.

The widths in the first direction FD and the second direction SD of the display panel 150 may be the same as the widths, respectively, in the first direction FD and the second direction SD of the polarizer 160.

Since the widths in the first direction FD and the second direction SD of the black adhesive layer 310 are larger than the widths, respectively, in the first direction FD and the second direction SD of the display panel 150, when viewed on a plane, the black adhesive layer 310 may include a part which surrounds the area where the display panel 150 is disposed and protrudes outward beyond the area where the display panel 150 is disposed.

Referring to (b) of FIG. 5, as described above, the widths in the first direction FD and the second direction SD of the support frame 110 may be the same as the widths, respectively, in the first direction FD and the second direction SD of the black adhesive layer 310.

The cover glass 170 may be disposed on the polarizer 160 and the black adhesive layer 310.

A part of the inner surface of the cover glass 170 may contact the upper surface of the polarizer 160 in the area where the display panel 150 is disposed.

A part of the lower surface of the cover glass 170 may contact a part of the upper surface of the black adhesive layer 310 in an area outside the area where the display panel 150 is disposed. In other words, the part of the upper surface of the black adhesive layer 310 which is located in the area outside the area where the display panel 150 is disposed when viewed on a plane may contact the lowermost surface 170a of the cover glass 170.

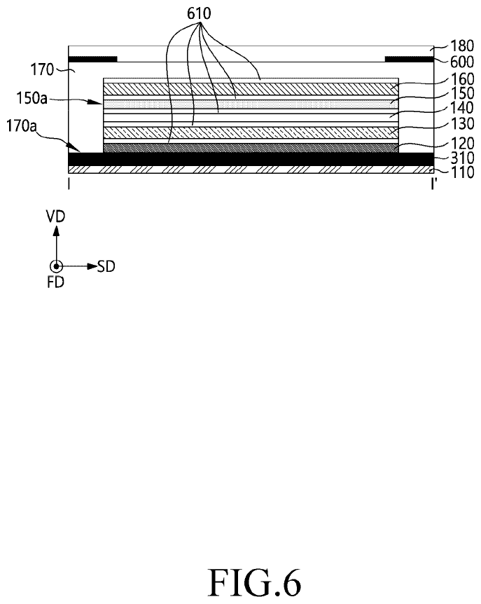

FIG. 6 is a view illustrating an example of the cross-sectional structure of a part I-I′ of FIG. 3.

In the following description, content overlapping the content described above with reference to FIGS. 3 to 5 will be omitted.

Adhesive layers 610 may be disposed between the first support layer 120 and a second support layer 130, between the second support layer 130 and a back plate 140, between the back plate 140 and the display panel 150, between the display panel 150 and the polarizer 160 and between the polarizer 160 and the cover glass 170. The adhesive layers 610 may serve to attach the respective layers, and may be, but are not limited to, optically clear adhesive (OCA) or pressure sensitive adhesive (PSA).

Referring to FIGS. 3 and 6, the cover glass 170 may extend in a direction parallel to the third direction VD on an area overlapping a part of the first side surface 150a of the display panel 150 where a non-folding area NFA is located.

The part of the cover glass 170 which extends in the direction parallel to the third direction VD may cover the part of the first side surface 150a of the display panel 150 which overlaps the non-folding area NFA.

The cover glass 170 may cover the entirety of the part of the first side surface 150a of the display panel 150 which overlaps the non-folding area NFA. However, the embodiments of the present disclosure are not limited thereto, and the cover glass 170 may cover only a portion of the part of the first side surface 150a of the display panel 150 which overlaps the non-folding area NFA.

Even in the case when the cover glass 170 covers only a portion of the part of the first side surface 150a of the display panel 150 which overlaps the non-folding area NFA, the lowermost surface 170a of the cover glass 170 may contact the upper surface of the black adhesive layer 310.

A black matrix 600 may be disposed in a partial area between the cover glass 170 and the shatterproof layer 180.

The black matrix 600 may be disposed in an area outside the area where the display panel 150 is disposed. However, the embodiments of the present disclosure are not necessarily limited thereto, and a part of the black matrix 600 may be disposed in the area where the display panel 150 is disposed.

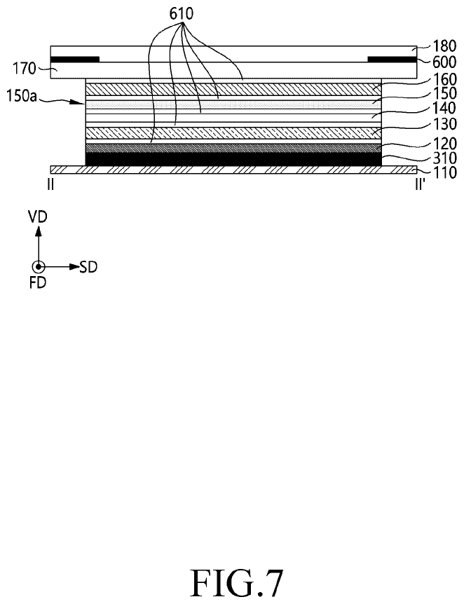

FIG. 7 is a view illustrating an example of the cross-sectional structure of a part II-II′ of FIG. 3.

Referring to FIGS. 3 and 7, the cover glass 170 may not extend in a direction parallel to the third direction VD in an area overlapping a folding area FA. Accordingly, the cover glass 170 may not be disposed on the first side surface 150a of the display panel 150 in the area overlapping the folding area FA.

In the area overlapping the folding area FA, the width in the second direction SD of the cover glass 170 may be the same as the width in the second direction SD of the support frame 110, and may be larger than the width in the second direction SD of the black adhesive layer 310.

In the area overlapping the folding area FA, the width in the second direction SD of the black adhesive layer 310 may be smaller than the width in the second direction SD of the support frame 110.

In the area overlapping the folding area FA, the width in the second direction SD of the black adhesive layer 310 may be the same as the width in the second direction SD of the display panel 150.

The thickness of the cover glass 170 in the area overlapping the folding area FA may be 30 um to 90 um.

The thickness of a part where the cover glass 170 overlaps the folding area FA on the first side surface 150a of the display panel 150 may be smaller than the thickness of a part where the cover glass 170 covers the first side surface 150a of the display panel 150 and overlaps the non-folding area NFA.

As described above, since the thickness of the cover glass 170 is thin in the area overlapping the folding area FA, the display apparatus 100 may realize a folding function. In addition, since the thickness of the cover glass 170 in an area overlapping the non-folding area NFA is larger than the thickness of the cover glass 170 disposed in the area overlapping the folding area FA, the impact resistance of the cover glass 170 may be reinforced.

FIG. 8 is a view illustrating an example of the cross-sectional structure of a part III-III′ of FIG. 3. Referring to FIGS. 3 and 8, the cover glass 170 may extend in a direction parallel to the third direction VD on a second side surface 150b of the two second side surfaces 150b of the display panel 150 to which the connecting part 151 is not connected.

As illustrated in FIG. 3, the cover glass 170 may extend in a direction parallel to the third direction VD on a part of a second side surface 150b of the two second side surfaces 150b of the display panel 150 to which the connection part 151 is connected.

Parts of the cover glass 170 which extend in directions parallel to the third direction VD may cover the entirety of the second side surface 150b of the two second side surfaces 150b of the display panel 150 to which the connection part 151 is not connected and may partially cover the second side surface 150b of the two second side surfaces 150b of the display panel 150 to which the connection part 151 is connected.

Since the connection part 151 and a circuit part 190 should be connected to one side surface of the display panel 150 to drive the display panel 150, the cover glass 170 may cover only an area which does not overlap the connection part 151 on the second side surface 150b of the two second side surfaces 150b of the display panel 150 to which the connection part 151 is connected.

Namely, on the second side surface 150b of the two second side surfaces 150b of the display panel 150 to which the connection part 151 is connected, the cover glass 170 may not extend in a direction parallel to the third direction VD in an area overlapping the connection part 151, but may extend in a direction parallel to the third direction VD in an area not overlapping the connection part 151.

As illustrated in FIG. 8, the connection part 151 may be bent in a direction parallel to the third direction VD, and the circuit part 190 attached to the connection part 151 may be attached to the lower surface of the support frame 110 through an adhesive layer.

In order to allow the connection part 151 to be bent in the direction parallel to the third direction VD, in an area where the connection part 151 is bent, the width in the first direction FD of the support frame 110 may be set to be smaller than the width in the first direction FD of the cover glass 170. For the same reason, the width in the first direction FD of the black adhesive layer 310 may be set to be smaller than the width in the first direction FD of the cover glass 170.

On the second side surface 150b of the two second side surfaces 150b of the display panel 150 to which the connection part 151 is connected, the thickness of the cover glass 170 in the area overlapping the connection part 151 may be 30 um to 90 um.

On the second side surface 150b of the two second side surfaces 150b of the display panel 150 to which the connection part 151 is connected, the thickness of the cover glass 170 in the area not overlapping the connection part 151 may be larger than the thickness of the cover glass 170 in the area overlapping the connection part 151.

The thickness of the cover glass 170 in the area not overlapping the connection part 151 may be the same as the thickness of the cover glass 170 which covers the first side surface 150a of the display panel 150 and overlaps the non-folding area NFA.

As described above, by setting the thickness of the cover glass 170 in the area overlapping the connection part 151 to be different from the thickness of the cover glass 170 in the area not overlapping the connection part 151, the impact resistance of the display apparatus 100 may be improved while defining a space in which the circuit part 190 may be connected to the display panel 150.

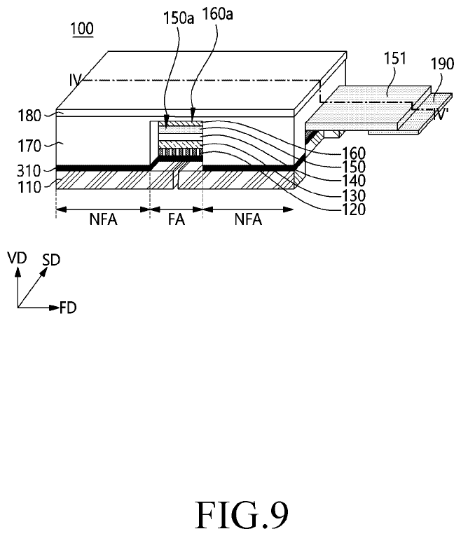

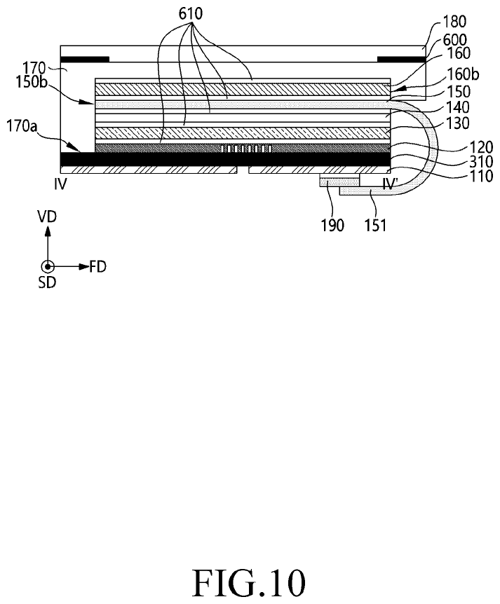

FIG. 9 is a view illustrating still another example of the three-dimensional structure of the display apparatus according to the embodiments of the present disclosure. FIG. 10 is a view illustrating an example of the cross-sectional structure of a part IV-IV′ of FIG. 9.

Since the display apparatus 100 illustrated in FIGS. 9 and 10 is the same as the display apparatus 100 illustrated in FIGS. 3 and 8 except that a length by which the cover glass 170, overlapping the connection part 151 on the second side surface 150b of the two second side surfaces 150b of the display panel 150 where the connection part 151 is located, extends in the third direction VD is increased, overlapping description will be omitted below.

Referring to FIGS. 9 and 10, on the second side surface 150b of the two second side surfaces 150b of the display panel 150 where the connection part 151 is located, the cover glass 170 may extend in a direction parallel to the third direction VD in the area overlapping the connection part 151, for example to the upper surface of the display panel 150.

In the area overlapping the connection part 151, the cover glass 170 may cover a second side surface 160b of the polarizer 160.

The polarizer 160 may include a first side surface 160a and the second side surface 160b. The first side surface 160a of the polarizer 160 may be located on the same plane as the first side surface 150a of the display panel 150, and the second side surface 160b of the polarizer 160 may be located on the same plane as the second side surface 150b of the display panel 150.

In the area overlapping the connection part 151, the cover glass 170 may cover the adhesive layer 610 between the polarizer 160 and the display panel 150.

The thickness of the cover glass 170 in the area overlapping the connection part 151 may be larger than the thickness of the cover glass 170 in an area where the cover glass 170 overlaps the area where the display panel 150 is disposed.

In the area overlapping the connection part 151, the thickness of the cover glass 170 may be larger than the thickness of the cover glass 170, described above with reference to FIGS. 3 and 8, in the area where the cover glass 170 overlaps the connection part 151. Accordingly, the impact resistance of the cover glass 170 may be improved in the area overlapping the connection part 151, and the connection part 151 and the circuit part 190 may be protected from external impact.

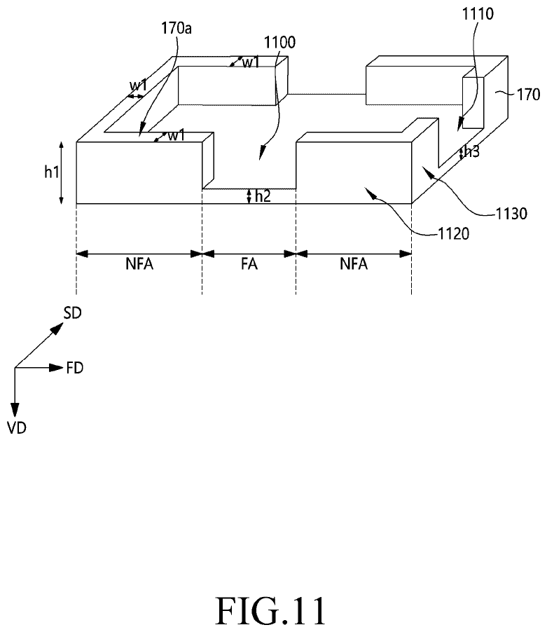

FIG. 11 is a view illustrating an example of the three-dimensional structure of a part of the configuration of the display apparatus illustrated in FIG. 3.

Referring to FIG. 11, the side surfaces of the cover glass 170 may include a first side surface 1120 and a second side surface 1130. The first side surface 1120 and the second side surface 1130 may meet each other. The first side surface 1120 and the second side surface 1130 may be perpendicular to each other, but are not necessarily limited thereto.

The first side surface 1120 of the cover glass 170 may be divided into a folding area FA and a non-folding area NFA around the folding area FA. The first side surface 1120 of the cover glass 170 may correspond to the first side surface of the display panel described above.

The thickness of a part of the first side surface 1120 of the cover glass 170 which overlaps the non-folding area NFA may be h1.

The first side surface 1120 of the cover glass 170 may include a first opening 1100 in an area overlapping the folding area FA.

The width of the first opening 1100 in the first direction FD may be the same as the width of the folding area FA, but is not limited thereto.

The thickness of the cover glass 170 in an area where the first opening 1100 is disposed may be h2.

h1 may be larger than h2.

The second side surface 1130 of the cover glass 170 may be divided into an area which overlaps the connection part described above and an area which does not overlap the connection part. The second side surface 1130 of the cover glass 170 may correspond to the second side surface of the display panel described above. The second side surface 1130 of the cover glass 170 may be a side surface which is perpendicular to the first side surface 1120.

The cover glass 170 may include a second opening 1110 on the second side surface 1130 of the cover glass 170.

The width in the second direction SD of the second opening 1110 may be the same as the width in the second direction SD of an area where the connection part is disposed, but is not limited thereto.

The thickness of the cover glass 170 in an area where the second opening 1110 is disposed may be h3.

h3 may be equal to h2, but is not necessarily limited thereto and may be larger than h2.

The width in the second direction SD of a part of a lowermost surface 170a of the cover glass 170 which is connected to the first side surface 1120 may be w1.

The width in the first direction FD of the lowermost surface 170a of the cover glass 170 which is connected to the second side surface 1130 may be w1.

Hereafter, the optimal thickness and width of the cover glass 170 for improving the impact resistance of the display apparatus will be described.

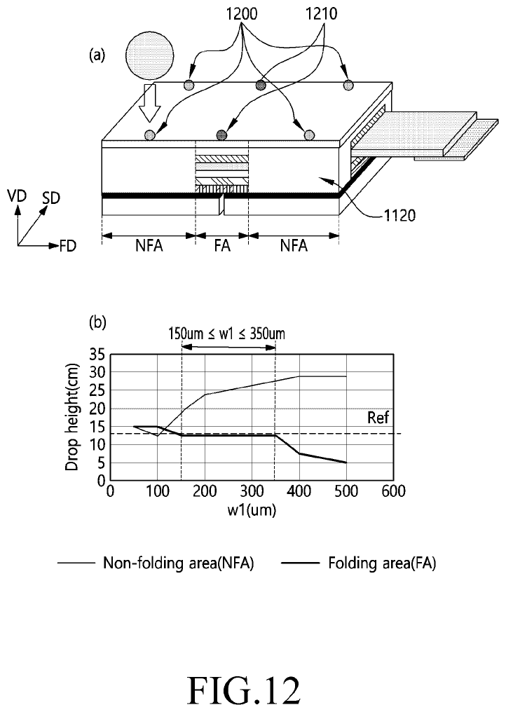

FIG. 12 is of a view and a graph for explaining impact resistance characteristics of the display apparatus according to the embodiments of the present disclosure.

Referring to (a) of FIG. 12, in order to check the impact resistance of the display apparatus, steel balls each weighing 22 g may be dropped from a predetermined height to four arbitrary points 1200 close to the first side surface 1120 of the cover glass 170 in the non-folding area NFA on the upper surface of the display apparatus and two arbitrary points 1210 close to the first side surface 1120 of the cover glass 170 in the folding area FA on the upper surface of the display apparatus.

Referring to (b) of FIG. 12, it may be seen that values, obtained by averaging, at the four points 1200 and the two points 1210, respectively, drop heights at which cracks occur in the cover glass 170 or defects occur in the driving of the display panel when the steel balls are dropped, vary depending on the width in the second direction SD of a surface of the lowermost surface 170a of the cover glass 170 which is connected to the first side surface 1120. As a drop height is higher, it may be meant that the impact resistance of the display apparatus is stronger.

A reference line Ref is a line corresponding to a height at which a crack starts to occur in the cover glass 170 or a defect starts to occur in the driving of the display panel when a steel ball is dropped in a case where the cover glass 170 has a thickness of 40 um in both the non-folding area NFA and the folding area FA, and the drop height of the steel ball at that time is 12.5 cm.

Since a drop height does not significantly vary compared to the reference line Ref in a case where the width in the second direction SD of the lowermost surface 170a of the cover glass 170 is 150 um or less when the steel ball is dropped in the non-folding area NFA, the width in the second direction SD of the lowermost surface 170a of the cover glass 170 may be set to be equal to or larger than 150 um.

Since a drop height in the non-folding area NFA increases as the width in the second direction SD of the lowermost surface 170a of the cover glass 170 increases, it may be seen that the impact resistance of the display apparatus increases.

However, it may be seen that, when the width in the second direction SD of the lowermost surface 170a of the cover glass 170 is equal to or larger than 350 um, a drop height in the folding area FA rather decreases.

That is to say, it may be seen that, if only the width in the second direction SD of the lowermost surface 170a of the cover glass 170 is increased in a state in which the thickness of the cover glass 170 is thin in the folding area FA, the impact resistance of the display apparatus decreases.

Therefore, the width in the second direction SD of the lowermost surface 170a of the cover glass 170, that is, w1, may 150 um to 350 um.

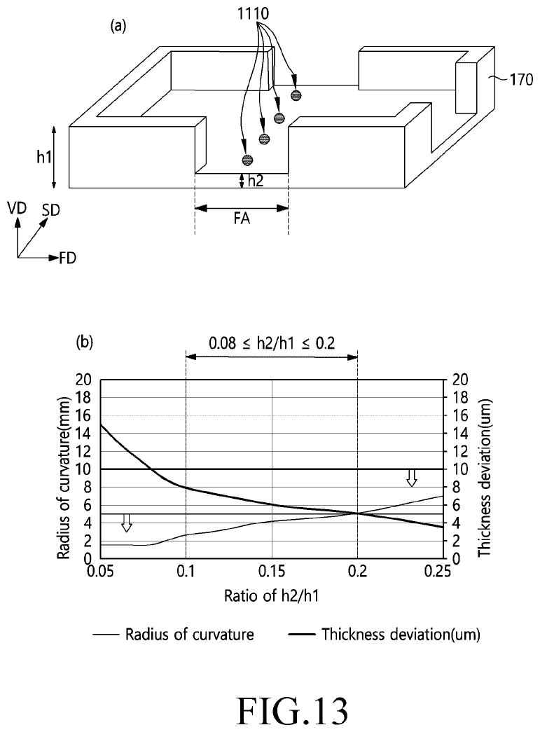

FIG. 13 is of a view and a graph for explaining curvature characteristics and etch uniformity characteristics of the display apparatus according to the embodiments of the present disclosure.

Referring to (a) of FIG. 13, by measuring the thicknesses of the cover glass 170 at four points 1110 on the inner surface of the cover glass 170 in an area where the cover glass 170 overlaps the folding area FA, from a value obtained by subtracting a minimum value from a maximum value, the etch uniformity or thickness deviation of the cover glass 170 may be checked.

Referring to (b) of FIG. 13, when the ratio of h2/h1, that is, the ratio of the thickness of the cover glass 170 in an area overlapping the folding area FA to the thickness of the cover glass 170 in an area overlapping the non-folding area NFA, is less than 0.08, the cover glass 170 should be etched relatively more in the folding area FA, and thus, thickness deviation may increase.

Therefore, the ratio of h2/h1 may be equal to or greater than 0.08.

When the ratio of h2/h1 is greater than 0.2, the radius of curvature increases, and thus, the folding characteristics of the display apparatus may deteriorate.

Therefore, the ratio of h2/h1 may be 0.08 to 0.2.

In order to secure folding characteristics in the folding area FA, h2 may be 30 um to 100 um, and h1 may be 430 um to 600 um.

Hereinafter, a method of manufacturing the cover glass 170 described above with reference to FIGS. 3 to 11 will be described.

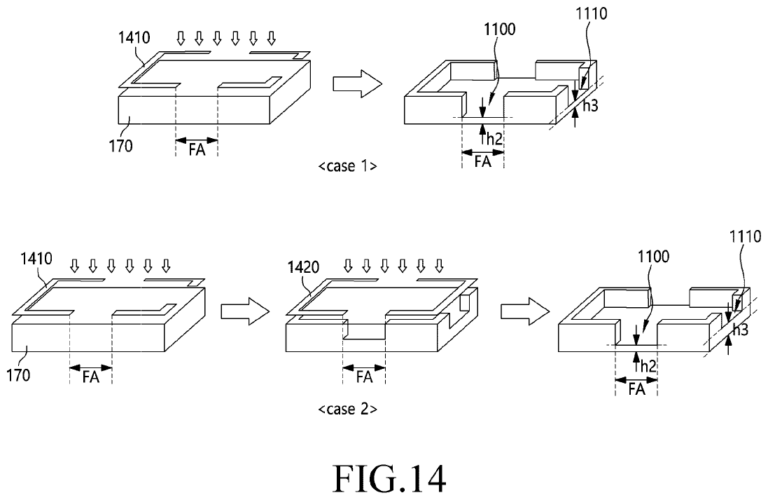

FIG. 14 is of views for explaining a method of manufacturing the structure illustrated in FIG. 11.

Referring to <case 1> of FIG. 14, the cover glass 170 may be etched using a first etch mask 1410.

The first etch mask 1410 may have a shape which is formed along the edges of the cover glass 170 with a predetermined width.

The first etch mask 1410 may cover parts of the edges of the cover glass 170.

Parts of the cover glass 170 excluding the parts covered by the first etch mask 1410 may be etched.

When the parts of the cover glass 170 excluding the parts covered by the first etch mask 1410 are etched, first openings 1100 and a second opening 1110 may be formed in the cover glass 170.

An area where the first opening 1100 is formed may be the folding area FA, and the thickness of the cover glass 170 in the area where the first opening 1100 is formed may be h2.

The thickness of the cover glass 170 in an area where the second opening 1110 is formed may be h3.

h2 and h3 may be the same.

Referring to <case 2> of FIG. 14, the cover glass 170 may be etched using a first etch mask 1410 and a second etch mask 1420.

The first etch mask 1410 is the same mask as the first etch mask 1410 of <case 1>.

The second etch mask 1420 may have a shape which is formed along the edges of the cover glass 170 with a predetermined width.

The second etch mask 1420 may cover parts of the edges of the cover glass 170.

An area where the second etch mask 1420 covers the edges of the cover glass 170 may be larger than an area where the first etch mask 1410 covers the edges of the cover glass 170.

The second etch mask 1420 may expose parts of edges in areas overlapping the folding area FA among the edges of the cover glass 170.

Parts of the cover glass 170 excluding parts covered by the first etch mask 1410 and the second etch mask 1420 may be etched.

When parts of the cover glass 170 excluding parts covered by the first etch mask 1410 are etched, first openings 1100 and a second opening 1110 may be formed in the cover glass 170.

The thickness of the cover glass 170 in an area where the first opening 1100 is formed and the thickness of the cover glass 170 in an area where the second opening 1110 is formed may be h3.

Thereafter, when parts of the cover glass 170 excluding parts covered by the second etch mask 1420 are etched, the thickness of the cover glass 170 in the area where the first opening 1100 is formed may be h2. However, the thickness of the cover glass 170 in the area where the second opening 1110 is formed may still be h3.

Since the cover glass 170 is etched once more in the area where the first opening 1100 is formed, h3 may be larger than h2.

Referring to FIGS. 13 and 14, the ratio of h3/h1, that is, the ratio of the thickness of the cover glass 170 in the area where the second opening 1110 is formed to the thickness of the cover glass 170 in an area overlapping the non-folding area NFA, may be 0.25 to 0.35. However, the embodiments of the present disclosure are not necessarily limited thereto.

After being etched, the cover glass 170 may be attached onto a polarizer through an adhesive layer. When attaching the cover glass 170 onto the polarizer, a diaphragm method may be used to ensure that pressure is evenly transferred to the inner surface of the cover glass 170.

That is to say, by attaching a separate protective film under the display apparatus, the respective layers of the display apparatus including the polarizer, the display panel, etc., may be attached to evenly fill the inside of the cover glass 170.

As described above with reference to FIG. 14, as the cover glass 170 is formed to have a plurality of openings in some areas while having parts with increased thicknesses compared to the conventional art, the display apparatus may have enhanced impact resistance while implementing a folding area.

Brief description of the embodiments of the present disclosure described above is as follows.

According to embodiments of the present disclosure, it is possible to provide a display apparatus including a display panel including a first side surface and a second side surface which meets the first side surface, the first side surface including a folding area and a non-folding area around the folding area; and a cover glass located on the display panel, and covering an area which overlaps the non-folding area of the first side surface of the display panel and at least a part of the second side surface of the display panel, wherein the thickness of a part of the cover glass which covers the first side surface of the display panel and is disposed in an area overlapping the non-folding area is larger than the thickness of a part of the cover glass which is disposed in an area overlapping the folding area.

In the display apparatus according to the embodiments of the present disclosure, each of the first side surface and the second side surface of the display panel may contact the cover glass.

In the display apparatus according to the embodiments of the present disclosure, the display apparatus may further include a plurality of support layers under the display panel, wherein the part of the cover glass which covers the first side surface of the display panel and is disposed in the area overlapping the non-folding area covers one side surfaces of the plurality of support layers.

In the display apparatus according to the embodiments of the present disclosure, a lower surface of the part of the cover glass which covers the first side surface of the display panel and is disposed in the area overlapping the non-folding area may be located on a same plane as a lower surface of a support layer located lowermost among the plurality of support layers.

In the display apparatus according to the embodiments of the present disclosure, the display apparatus may further include a support frame disposed under the plurality of support layers, wherein an outer surface of the support frame is located on the same plane as an outer surface of the cover glass.

In the display apparatus according to the embodiments of the present disclosure, the display apparatus may further include an adhesive layer disposed between the plurality of support layers and the support frame, wherein the adhesive layer is disposed between the cover glass and the support frame in an area other than an area where the plurality of support layers are disposed.

In the display apparatus according to the embodiments of the present disclosure, the display apparatus may further include a shatterproof layer disposed on the cover glass, wherein the shatterproof layer and the cover glass are directly contact each other in an area overlapping a surface at which the cover glass and the adhesive layer contact each other.

In the display apparatus according to the embodiments of the present disclosure, the display apparatus may further include a circuit part connected to the display panel on the second side surface of the display panel, wherein the thickness of a part of the cover glass which covers at least the part of the second side surface of the display panel is larger than the thickness of a part of the cover glass disposed in an area overlapping a location on the second side surface of the display panel where the circuit part is connected.

In the display apparatus according to the embodiments of the present disclosure, the thickness of the part of the cover glass disposed in the area overlapping the location on the second side surface of the display panel where the circuit part is connected may be different from the thickness of a part of the cover glass which covers the first side surface of the display panel and is disposed in an area overlapping the non-folding area.

In the display apparatus according to the embodiments of the present disclosure, the thickness of the part of the cover glass disposed in the area overlapping the location on the second side surface of the display panel where the circuit part is connected may be larger than the thickness of a part of the cover glass which covers the first side surface of the display panel and is disposed in an area overlapping the folding area.

According to embodiments of the present disclosure, it is possible to provide a display apparatus including a display panel including a first side surface and a second side surface perpendicular to the first side surface; and a cover glass located on the display panel, and covering at least a part of the first side surface and at least a part of the second side surface, wherein the thickness of a part of the cover glass which covers the first side surface is different from the thickness of a part of the cover glass which overlaps the first side surface and does not cover the first side surface.

In the display apparatus according to the embodiments of the present disclosure, the first side surface may be divided into a folding area and a non-folding area, and the cover glass may cover the first side surface in an area overlapping the non-folding area.

In the display apparatus according to the embodiments of the present disclosure, the thickness of the part of the cover glass which covers the first side surface may be larger than the thickness of the part of the cover glass which overlaps the first side surface and does not cover the first side surface.

In the display apparatus according to the embodiments of the present disclosure, each of the first side surface and the second side surface of the display panel may contact the cover glass.

In the display apparatus according to the embodiments of the present disclosure, the display apparatus may further include a plurality of support layers under the display panel, wherein a lower surface of the part of the cover glass which covers the first side surface of the display panel is located on a same plane as a lower surface of a support layer located lowermost among the plurality of support layers.

In the display apparatus according to the embodiments of the present disclosure, the display apparatus may further include a circuit part connected to the display panel on the second side surface of the display panel, wherein the thickness of a part of the cover glass which covers the second side surface of the display panel is larger than the thickness of a part of the cover glass which is disposed in an area overlapping a location on the second side surface of the display panel where the circuit part is connected.

In the display apparatus according to the embodiments of the present disclosure, the thickness of the part of the cover glass which is disposed in the area overlapping the location on the second side surface of the display panel where the circuit part is connected may be different from the thickness of the part of the cover glass which covers the first side surface of the display panel.

According to embodiments of the present disclosure, it is possible to provide a display apparatus including a display panel; and a cover glass located on the display panel, and including a first opening which overlaps one side surface of the display panel and a second opening which overlaps the other side surface of the display panel, wherein the display panel is located inside the cover glass in an area overlapping the first opening, and protrudes to an outside of the cover glass in an area overlapping the second opening.

In the display apparatus according to the embodiments of the present disclosure, the display panel may include at least one folding area, and the folding area may overlap an area where the first opening is disposed.

In the display apparatus according to the embodiments of the present disclosure, the display apparatus may further include a circuit part connected to the display panel, wherein an area where the circuit part is disposed overlaps an area where the second opening is disposed.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a display panel including a first side surface and a second side surface, the second side surface meets the first side surface, the first side surface including a folding area and a non-folding area around the folding area; and
a cover glass located on the display panel, wherein a first part of the cover glass covers an area of the display panel including at least a part of the non-folding area of the first side surface of the display panel and at least a part of the second side surface of the display panel,
wherein a thickness of the first part of the cover glass is greater than a thickness of a second part of the cover glass which covers the folding area.

2. The display apparatus of claim 1, wherein each of the first side surface and the second side surface of the display panel contacts the cover glass.

3. The display apparatus of claim 1, further comprising:
a plurality of support layers under the display panel,
wherein the first part of the cover glass covers one side surface of each of the plurality of support layers.

4. The display apparatus of claim 3, wherein a lower surface of the first part of the cover glass is located on a same plane as a lower surface of a lowermost support layer of the plurality of support layers.

5. The display apparatus of claim 3, further comprising:
a support frame disposed under the plurality of support layers,
wherein an outer surface of the support frame is located on a same plane as an outer surface of the cover glass.

6. The display apparatus of claim 1, further comprising:
a circuit connected to the display panel on the second side surface of the display panel,
wherein the thickness of the second part of the cover glass is greater than a thickness of a third part of the cover glass disposed in an area overlapping a location on the second side surface connected to the circuit.

7. The display apparatus of claim 6, wherein the thickness of the third part of the cover glass is different from the thickness of the first part of the cover glass.

8. The display apparatus of claim 7, wherein the thickness of the third part of the cover glass is greater than the thickness of the first part of the cover glass.

9. A display apparatus, comprising:
a display panel including a first side surface and a second side surface perpendicular to the first side surface; and
a cover glass located on the display panel, and covering at least a part of the first side surface and at least a part of the second side surface,
wherein a thickness of a first part of the cover glass which covers the first side surface is different from a thickness of a second part of the cover glass which overlaps the first side surface and does not cover the first side surface.

10. The display apparatus of claim 9, wherein the first side surface includes a folding area and a non-folding area, and the first part of the cover glass covers the first side surface in an area overlapping the non-folding area.

11. The display apparatus of claim 9, wherein the thickness of the first part of the cover glass is greater than the thickness of the second part of the cover glass.

12. The display apparatus of claim 9, wherein each of the first side surface and the second side surface of the display panel contacts the cover glass.

13. The display apparatus of claim 9, further comprising:
a plurality of support layers under the display panel,
wherein a lower surface of the first part of the cover glass is located on a same plane as a lower surface of a lowermost support layer of the plurality of support layers.

14. The display apparatus of claim 9, further comprising:
a circuit connected to the display panel on the second side surface of the display panel,
wherein the thickness of a part of the cover glass which covers the second side surface of the display panel is greater than a thickness of a third part of the cover glass which is disposed in an area overlapping a location on the second side surface of the display panel connected to the circuit part.

15. The display apparatus of claim 14, wherein the thickness of the third part of the cover glass is different from the thickness of the first part of the cover glass.

16. A display apparatus comprising:
a display panel including a first side surface extending in a first direction and a second side surface extending in a second direction; and
a cover glass located on the display panel, and extending in a direction parallel to a third direction in an area other than the area where the display panel is disposed to cover at least a part of the first side surface and at least a part of the second side surface, the third direction being perpendicular to the first direction and the second direction.

17. The display apparatus of claim 16, wherein
the first side surface includes a folding area and a non-folding area around the folding area, and
the part of the cover glass which extends in the direction parallel to the third direction covers at least part of the area of the first side surface of the display panel which overlaps the non-folding area.

18. The display apparatus of claim 17, wherein
the cover glass does not extend in a direction parallel to the third direction in an area overlapping the folding area.

19. The display apparatus of claim 17, wherein
the display panel has a connection portion disposed on the second side surface for connecting to a circuit portion, and
the cover glass extends in a direction parallel to the third direction in an area not overlapping the connection part, on the second side surface on which the connection portion is disposed.

20. The display apparatus of claim 19, wherein
the cover glass does not extend in a direction parallel to the third direction or extends in a direction parallel to the third direction to the upper surface of the display panel in an area overlapping the connection part, on the second side surface on which the connection portion is disposed.
